(19) United States
(12) Patent Application Publication
(10) Pub. No.: US 2025/0155507 A1
(43) Pub. Date: May 15, 2025

(54) ISOLATION DETECTION

(71) Applicant: Our Next Energy, Inc., Novi, MI (US)

(72) Inventor: Yan Zhou, Novi, MI (US)

(21) Appl. No.: 18/946,896

(22) Filed: Nov. 13, 2024

Related U.S. Application Data
(60) Provisional application No. 63/598,636, filed on Nov. 14, 2023.

(51) Int. Cl. G01R 31/36; G01R 19/00; G01R 27/02; G01R 31/389; H01M 10/48

(52) U.S. Cl. CPC G01R 31/3648; G01R 19/0084; G01R 27/025; G01R 31/389; H01M 10/482

(57) ABSTRACT

Providing a first battery and a second battery, coupling a negative terminal of the first battery to a positive terminal of the second battery at a coupling point, such that the first battery and the second battery are coupled in series, closing a first set of switches of the corresponding isolation detection circuitry of the first battery and of the second battery, and sensing a first voltage between the coupling point and a chassis ground, closing a second set of switches of the corresponding isolation detection circuitry of the first battery and of the second battery, and sensing a second voltage between the coupling point and the chassis ground, computing a total isolation resistance based on at least the first voltage and the second voltage.

### BACKGROUND

### Technical Field

The present disclosure generally relates to isolation detection and more particularly to isolation detection based on measuring the total isolation resistance of a system comprising a plurality of batteries coupled in series.

### Description of the Related Art

Battery packs produce electrical energy to provide power to an electrical system, such as an electric vehicle (EV) or an energy storage system (ESS). The energy is stored in cells that are all connected to one another in the battery pack.

Components of battery systems are usually electrically isolated from each other for safety. When isolation failures occur due to, for example, manufacturing defects, physical damage, or gradual wear and tear, there is the potential of hazardous situations arising including short circuits, electrical arcing, and thermal runaway, which can then lead to electrocution, fires, explosions, or damage to the battery system.

### BRIEF SUMMARY

According to an embodiment of the present disclosure, a method is disclosed including providing a first battery and a second battery, coupling a negative terminal of the first battery to a positive terminal of the second battery at a coupling point, such that the first battery and the second battery are coupled in series, closing a first set of switches of the corresponding isolation detection circuitry of the first battery and of the second battery, and sensing a first voltage between the coupling point and a chassis ground. The method also includes closing a second set of switches of the corresponding isolation detection circuitry of the first battery and of the second battery and sensing a second voltage between the coupling point and the chassis ground and computing a total isolation resistance based at least on the first voltage and the second voltage.

In one embodiment, the first set of switches and the second set of switches are selected to create electrical paths in different scenarios such that the total isolation resistance can be computed based on at least the first voltage and the second voltage without a need to individually compute any individual isolation resistances that make up the total isolation resistance.

In one embodiment, the total isolation resistance is computed automatically and/or periodically based on control of switches of the isolation detection circuitry of the individual batteries.

According to an embodiment, a system is disclosed that includes a first battery and a second battery, each battery including a corresponding isolation detection circuitry. The system also includes a negative terminal of the first battery coupled to a positive terminal of the second battery at a coupling point, such that the first battery and the second battery are coupled in series. The system also includes a processor configured to close a first set of switches of the corresponding isolation detection circuitry of the first battery and of the second battery, and obtain, via a voltage measurement device, a first voltage between the coupling point and a chassis ground. The processor is further configured to close a second set of switches of the corresponding isolation detection circuitry of the first battery and of the second battery, and obtain, via a voltage measurement device, a second voltage between the coupling point and the chassis ground. The processor is further configured to compute a total isolation resistance based on at least the first voltage and the second voltage.

In one embodiment, each battery is modular, is a battery pack, and includes a corresponding isolation detection circuitry.

In one embodiment, each battery includes multiple battery packs that are coupled in series.

### BRIEF DESCRIPTION OF THE DRAWINGS

To easily identify the discussion of any particular element or act, the most significant digit or digits in a reference number refer to the figure number in which that element is first introduced.

FIG. 1 depicts a drivetrain and energy storage components in accordance with illustrative embodiments.

FIG. 2 depicts a block diagram of a battery pack arrangement in accordance with an illustrative embodiment.

FIG. 3 depicts a schematic diagram of two batteries coupled in series in accordance with illustrative embodiments.

FIG. 4 depicts a schematic diagram of two batteries coupled in series, each battery comprising an isolation detection circuitry in accordance with illustrative embodiments.

FIG. 5 depicts a routine in accordance with illustrative embodiments.

FIG. 6 depicts a schematic diagram of two batteries coupled in series, and a first set of switches closed in accordance with illustrative embodiments.

FIG. 7 depicts a schematic diagram of two batteries coupled in series, and a second set of switches closed in accordance with illustrative embodiments.

FIG. 8 depicts a schematic diagram a voltage measurement device across a second resistor in accordance with illustrative embodiments.

FIG. 9 depicts a schematic diagram of two batteries coupled in series, and the first battery including a plurality of battery packs in accordance with illustrative embodiments.

FIG. 10 depicts a schematic diagram of two batteries coupled in series, the first battery including a plurality of battery packs, a first set of switches closed in accordance with illustrative embodiments.

FIG. 11 depicts a schematic diagram of two batteries coupled in series, the first battery including a plurality of battery packs, a second set of switches closed in accordance with illustrative embodiments.

FIG. 12 depicts a schematic diagram of two batteries coupled in series, the second battery including a plurality of battery packs, a first set of switches closed in accordance with illustrative embodiments.

FIG. 13 depicts a schematic diagram of two batteries coupled in series, the second battery including a plurality of battery packs, a second set of switches closed in accordance with illustrative embodiments.

FIG. 14 depicts a functional block diagram of a computer hardware platform in accordance with illustrative embodiments.

### DETAILED DESCRIPTION

In the following detailed description, numerous specific details are set forth by way of examples to provide a thorough understanding of the relevant teachings. However, it should be apparent that the present teachings may be practiced without such details. In other instances, well-known methods, procedures, and/or components have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below”, or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a cell. As used herein, the term “vertical” describes an orientation that is arranged perpendicular to the first surface of a cell.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

For the sake of brevity, conventional techniques related to battery packs and their use may or may not be described in detail herein. Moreover, the various tasks and process steps described herein can be incorporated into a more comprehensive procedure or process having additional steps or functionality not described in detail herein.

Turning now to an overview of technologies that generally relate to the present teachings, isolation detection involves detecting whether two components are electrically isolated from each other. This may be crucial for safety and to prevent electrical faults and electrocution especially in high-voltage systems. The illustrative embodiments recognize that isolation detection may include measuring a resistance between two points in a circuit. Based on the measured resistance, one can determine the existence of an unintended connection (low resistance relative to a threshold) between the two points, or the isolation of the two points (high resistance relative to the threshold). However, a challenge arises when a plurality of battery packs are connected together. Dedicated external isolation detection solutions that are external to the battery pack system may be adopted for isolation detection purposes and this may be expensive, time consuming, complex, and significantly inconvenient especially in highly modular power supply systems in which different configurations of the battery packs may be frequently utilized.

The illustrative embodiments disclose a method comprising coupling a negative terminal of a first battery to a positive terminal of a second battery at a coupling point such that the first battery and the second battery are coupled in series, closing a first set of switches of an isolation detection circuitry of the first battery and of the second battery and sensing a first voltage between the coupling point and a chassis ground, closing a second set of switches of the isolation detection circuitry of the first battery and of the second battery and sensing a second voltage between the coupling point and the chassis ground, and computing a total isolation resistance of the series coupled batteries based on at least the first voltage and the second voltage.

### Example Vehicle System

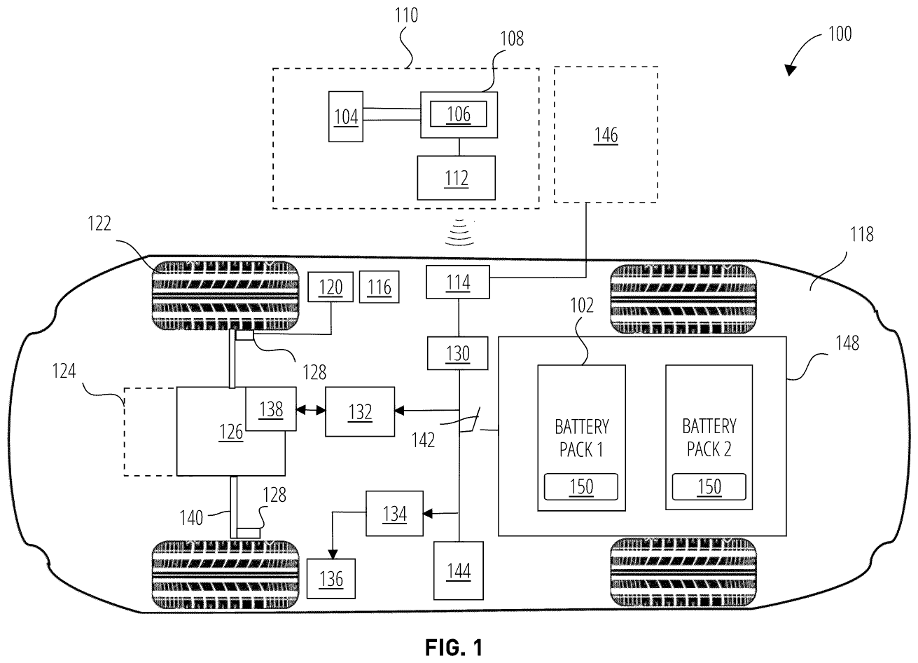

Turning to FIG. 1, a schematic of a generalized electric vehicle system 100 in which a battery pack 102 of a plurality of battery packs 148 may be housed will be described. It will become apparent to a person skilled in the relevant art(s) that the concepts described herein are directed to battery packs used in all electrified/electric vehicles, including, but not limited to, battery electric vehicles (BEV's), plug-in hybrid electric vehicles, motor vehicles, railed vehicles, watercraft, and aircraft configured to utilize rechargeable electric batteries as their main source of energy to power their drive systems propulsion or that possess an all-electric drivetrain. The concepts may also apply to any other applications in which an energy supply is utilized, such as in a home or commercial energy storage system.

The electric vehicle 118 may comprise one or more electric machines 138 mechanically connected to a transmission 126. The electric machine 138 may be capable of operating as a motor or a generator. In addition, the transmission 126 may be mechanically connected to an engine 124, as in a PHEV. The transmission 126 may also be mechanically connected to a drive shaft 140 that is mechanically connected to the wheels 120. The electric machine 138 can provide propulsion and deceleration capability when the engine 124 is turned on or off. The electric machine 138 also act as generators and can provide fuel economy benefits by recovering energy that would normally be lost as heat in the friction braking system. The electric machine 138 may also reduce vehicle emissions by allowing the engine 124 to operate at more efficient speeds and allowing the electric vehicle 118 to be operated in electric mode with the engine 124 off in the case of hybrid electric vehicles.

A battery pack 102 stores energy that can be used by the electric machine 138. The battery pack 102 typically provides a high voltage DC output and may be electrically connected to one or more power electronics modules 132. A battery pack may also include one of more modules each including a plurality of cells. Terminals of cells of the battery pack 102 may be tapped through one or more interconnects. Each battery pack 102 may also include an isolation detection circuitry 150 configured to detect the isolation of the battery pack. Further, by operating sets of switches in isolation detection circuitries 150 of series coupled battery packs 102, the electrical isolation of the series coupled battery packs 102 may be determined based on the use of already existing isolation circuitries in the housing of the battery packs 102. One or more isolating contactors 142 may further isolate the battery packs 102 from other components when opened and connect the battery pack 102 to other components when closed. The battery pack assembly may in some cases have a cell-to-pack arrangement. For example, a battery pack may include cells directly placed in an enclosure without the use of separate modules, with the enclosure also housing other hardware such as, but not limited to a pre-charge circuit, power electronics module 132, DC/DC converter module 134, system controller 116 (such as a battery management system (BMS)), power conversion module 130, battery thermal management system (cooling system and electric heaters) and isolating contactors 142.

The power electronics module 132 may also electrically connected to the electric machine 138 and may provide the ability to bi-directionally transfer energy between the battery pack 102 and the electric machine 138. For example, a traction or range-extender battery may provide a DC voltage while the electric machine 138 may operate using a three-phase AC current. The power electronics module 132 may convert the DC voltage to a three-phase AC current for use by the electric machine 138. In a regenerative mode, the power electronics module 132 may convert the three-phase AC current from the electric machine 138 acting as generators to the DC voltage compatible with the battery pack 102. The description herein is equally applicable to a BEV. For a BEV, the transmission 126 may be a gear box connected to an electric machine 138 and the engine 124 may not be present.

In addition to providing energy for propulsion, the battery packs 102 may provide energy for other vehicle electrical systems. A typical system may include a DC/DC converter module 134 that converts the high voltage DC output of the battery pack 102 to a low voltage DC supply that is compatible with other vehicle loads. Other electrical loads 144, such as compressors and electric heaters, may be connected directly to the high-voltage bus without the use of a DC/DC converter module 134. The low-voltage systems may be electrically coupled to an auxiliary battery 136 (e.g., 12V battery).

The battery packs 102 may be recharged by a charging system such as a wireless vehicle charging system 110 or a plug-in charging system 146. The wireless vehicle charging system 110 may include an external power source 104. The external power source 104 may be a connection to an electrical outlet. The external power source 104 may be electrically coupled to electric vehicle supply equipment 108 (EVSE). The electric vehicle supply equipment 108 may provide an EVSE controller 106 to provide circuitry and controls to regulate and manage the transfer of energy between the external power source 104 and the electric vehicle 118. The external power source 104 may provide DC or AC electric power to the electric vehicle supply equipment 108. The electric vehicle supply equipment 108 may be coupled to a transmit coil 112 for wirelessly transferring energy to a receiver 114 of the vehicle 118 (which in the case of a wireless vehicle charging system 110 is a receive coil). The receiver 114 may be electrically coupled to a charger or on-board power conversion module 136. The receiver 114 may be located on an underside of the electric vehicle 118. In the case of a plug-in charging system 146, the receiver 114 may be a plug-in receiver/charge port and may be configured to charge the battery packs 102 upon insertion of a plug-in charger. The power conversion module 130 may condition the power supplied to the receiver 114 to provide the proper voltage and current levels to the battery pack 102. The power conversion module 130 may interface with the electric vehicle supply equipment 108 to coordinate the delivery of power to the electric vehicle 118.

One or more wheel brakes 128 may be provided for decelerating the electric vehicle 118 and preventing motion of the electric vehicle 118. The wheel brakes 128 may be hydraulically actuated, electrically actuated, or some combination thereof. The wheel brakes 128 may be a part of a brake system 120. The brake system 120 may include other components to operate the wheel brakes 128. For simplicity, the figure depicts a single connection between the brake system 120 and one of the wheel brakes 128. A connection between the brake system 120 and the other wheel brakes 126 is implied. The brake system 120 may include a controller to monitor and coordinate the brake system 120. The brake system 120 may monitor the brake components and control the wheel brakes 128 for vehicle deceleration. The brake system 120 may respond to driver commands and may also operate autonomously to implement features such as stability control. The controller of the brake system 120 may implement a method of applying a requested brake force when requested by another controller or sub-function.

### Example Battery Pack

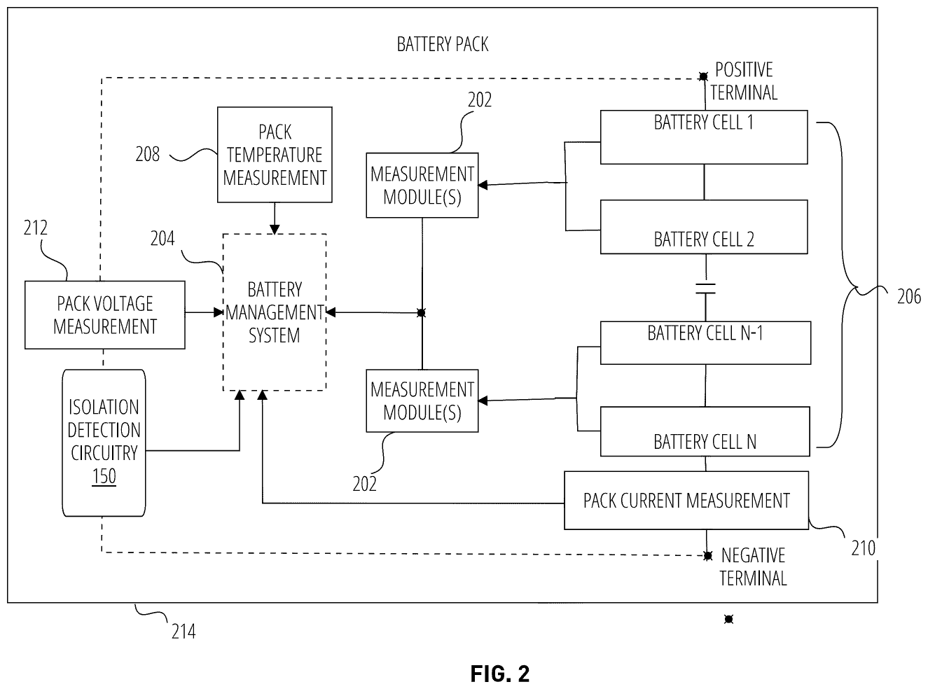

Turning now to FIG. 2, an example battery pack is disclosed to illustrate components thereof. Other battery pack arrangements, however, may be composed of any number of individual cells 206 coupled in series or parallel or some combination thereof. The battery pack 102 may also have controllers such as the battery management system (BMS 204) that monitors and controls the performance of the cells 206, switches of the isolation detection circuitry 150 and/or battery pack 102 as a whole. The BMS 204 may monitor several battery pack level characteristics such as pack current 210, short circuits, pack voltage 212 and pack temperature 208. For example, a voltage measurement apparatus may be used to measure pack voltage. The BMS 204 may have non-volatile memory such that data may be retained when the BMS 204 is in an off condition. Retained data may be available upon the next key cycle. The BMS 204 may alternatively be located outside the battery pack and may be configured to control a plurality of battery packs and their corresponding pre-charge circuits.

In addition to monitoring the pack level characteristics, there may be cell 206 level characteristics that are measured and monitored. A system may use a measurement module(s) 202 to measure the combined cell 206 characteristics. Depending on the capabilities, the measurement module(s) 202 may measure the characteristics of one or multiple of the cells 206. Each measurement module(s) 202 may transfer the measurements to the BMS 204 for further processing and coordination. The measurement module(s) 202 may be as simple as one or more switches or leads operated to provide a coupling to the one or more cells. The measurement module(s) 202 may transfer signals in analog or digital form to the BMS 204. In some embodiments, the measurement module(s) 202 functionality may be incorporated internally to the BMS 204. That is, the measurement module(s) 202 comprise hardware that may be integrated as part of the circuitry in the BMS 204 and the BMS 204 may handle the processing of raw signals. Further, the BMS 204 may in some cases be embodied in the form of an electronic measurement device disposed on each of the cells as discussed herein.

It may be useful to calculate various characteristics as well as configuration of a plurality of battery packs. Quantities such a battery power capability and battery state of charge, battery voltage etc., may be useful for controlling the operation of the battery packs as well as any electrical loads receiving power from the battery packs.

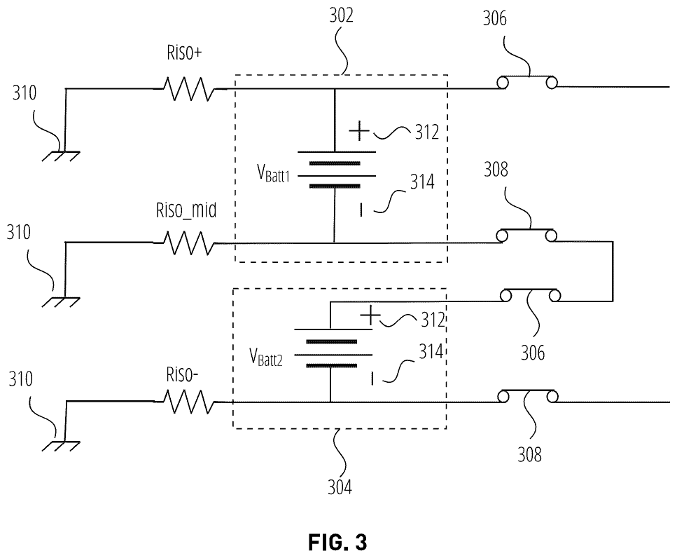

Turning now to FIG. 3, a schematic diagram of two batteries coupled in series is illustrated. The batteries comprise a first battery 302 and a second battery 304 that may be stacked in series in some applications, via positive contactor 306 and or negative contactor 308, to achieve higher total voltage and higher total power. In some embodiments, the batteries may each be structured as a battery pack 102 comprising a battery pack housing. To detect or compute an isolation of the series coupled first and second battery, the resistance between the packs and chassis ground 310 may be measured. As shown in FIG. 3, isolation failure may show up as a resistance between the positive terminal 312 of the first battery 302 and the chassis ground 310 (i.e., Riso+), a resistance between the negative terminal 314 of the first battery 302 or the positive terminal 312 of the second battery 304 and the chassis ground 310 (i.e., Riso_mid), and/or a resistance between the negative terminal 314 of the second battery 304 and the chassis ground 310 (i.e., Riso−). In an aspect, an operator may be informed when the total isolation resistance Rᵢₛₒ_{ₜₒₜₐₗ} is below a predetermined safety threshold. Total isolation resistance Risotto may be the parallel resistance of Riso+, Riso− and Riso_mid.

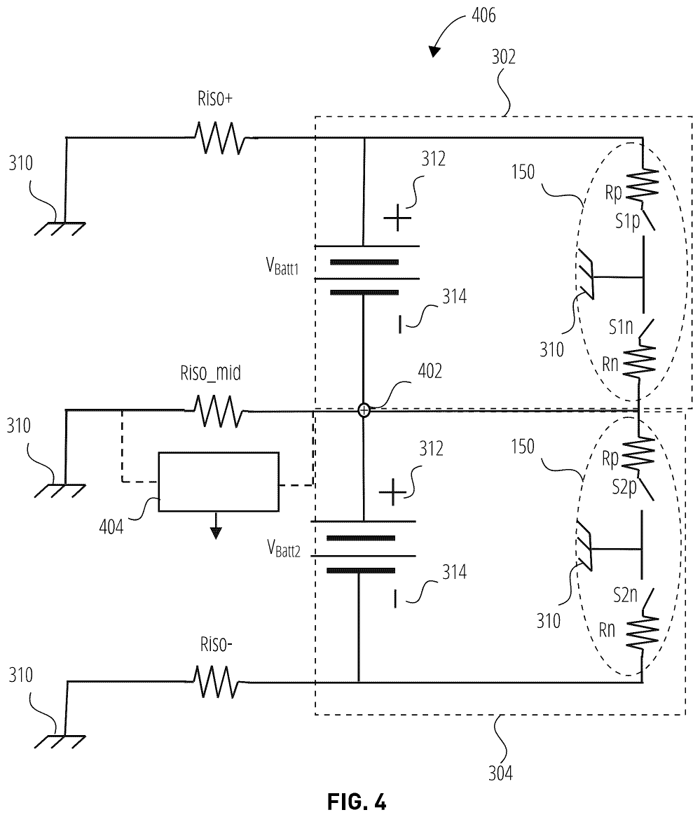

FIG. 4 illustrates a schematic diagram of a power supply system 406 showing two batteries coupled in series, each battery comprising an isolation detection circuitry 150 in accordance with illustrative embodiments. The power supply system 406 comprises the first battery 302 and the second battery 304, each battery including one or more cells that are coupled in parallel with a corresponding isolation detection circuitry 150. The negative terminal 314 of the first battery 302 is coupled to the positive terminal 312 of the second battery 304 at a coupling point 402, such that the first battery and the second battery are coupled in series. A voltage of the one or more cells of the first battery 302 may be Vbatt1 and a voltage of the one or more cells of the second battery 304 may be Vbatt2.

A voltage measurement device 404 measures the voltage between the coupling point 402 and the chassis ground 310 when the circuit is closed. The isolation detection circuitry 150 of the first battery 302 comprises a first resistor Rp, a second resistor Rn, a first switch S1p, and, and a second switch S1n. Likewise, the isolation detection circuitry 150 of the second battery 304 comprises a first resistor Rp, a second resistor Rn, a first switch S2p, and, and a second switch S2n. The resistance of the first resistor Rp is the same in all isolation detection circuitries 150 of the power supply system 406. Likewise, the resistance of the second resistor Rn is the same in all isolation detection circuitries 150 of the power supply system 406.

In each isolation detection circuitry 150, one side of the first resistor Rp is coupled to a positive terminal 312 of the battery and another side of the first resistor Rp is coupled to a first switch (e.g., switch S1p of the first battery). The first switch is electrically coupled to the chassis ground 310 when closed. In each isolation detection circuitry 150, one side of the second resistor Rn is coupled to the negative terminal 314 of the battery and another side of the second resistor Rn is coupled to a second switch (e.g., switch SIn of the first battery). The second switch is also electrically coupled to the chassis ground 310 when closed.

In an aspect, the first battery 302 and/or the second battery 304 are each structured as a battery pack 102 comprising a plurality of cells 206 disposed in a battery pack housing 214 along with the corresponding isolation detection circuitry 150. Further the first battery 302 and/or the second battery 304 may each comprise or be a plurality of battery packs coupled in series, as discussed hereinafter. Thus, the first battery 302 and/or the second battery 304 may each comprise one or more battery packs (or sub-packs) coupled in series with each battery pack (or sub-pack) comprising a corresponding isolation detection circuitry 150 that is operable by the BMS 204 or one or more processors.

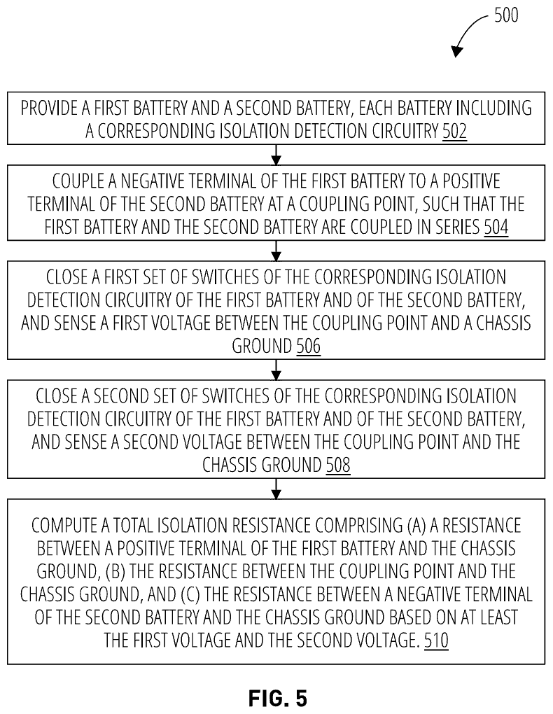

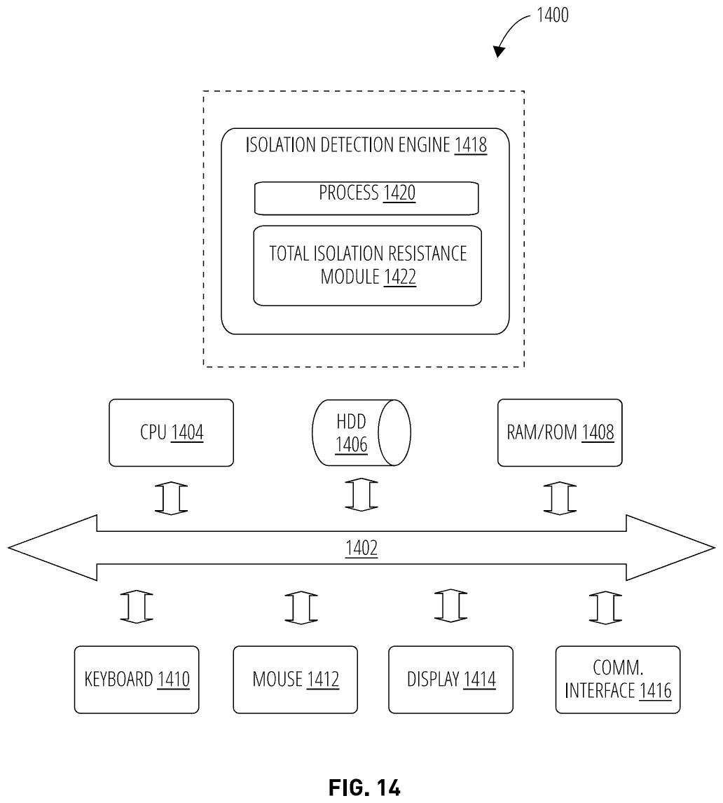

FIG. 5 illustrates a resistance measurement routine 500 in accordance with illustrative embodiments. The resistance measurement routine 500 may be performed using the isolation detection engine 1418 of FIG. 14. As discussed herein, isolation failure may show up as Riso+, Riso− and Riso_mid. By sequentially operating the switches of the isolation detection circuitries 150 of the power supply system 406, the voltage between the coupling point 402 and the chassis ground 310 may be measured in different closed-circuit scenarios and used to compute the total isolation resistance Rᵢₛₒ_{ₜₒₜₐₗ} without a need to know any of Riso+, Riso− or Riso_mid.

In block 502, isolation detection engine 1418 may provide the first battery 302 and the second battery 304, each battery including a corresponding isolation detection circuitry 150. In block 504, isolation detection engine 1418 may couple a negative terminal 314 of the first battery 302 to a positive terminal 312 of the second battery 304 at a coupling point 402, such that the first battery 302 and the second battery 304 are coupled in series.

In block 506, isolation detection engine 1418 may close a first set of switches of the corresponding isolation detection circuitry 150 of the first battery 302 and of the second battery 304, and sense a, using the voltage measurement device 404, first voltage V_{s_a} between the coupling point 402 and a chassis ground 310.

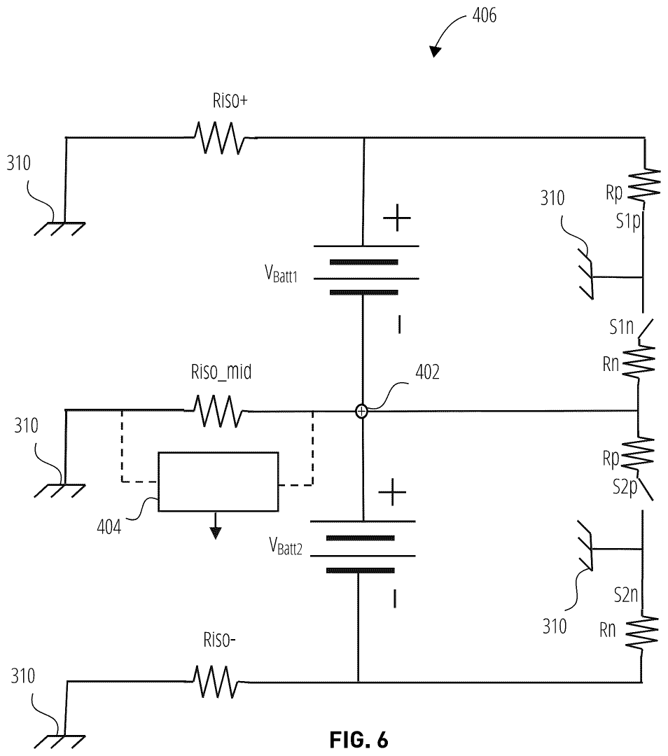

More specifically, the first set of switches include switches S1p and S2n, as shown in FIG. 6. The first voltage V_{s_a} may be obtained by:

$${V}_{s\_a} = \frac{{V}_{Batt 1} ( {Y}_{iso +} + {Y}_{p} ) - {V}_{Batt 2} ( {Y}_{iso -} + {Y}_{n} )}{{Y}_{iso +} + {Y}_{iso -} + {Y}_{iso\_mid} + {Y}_{p} + {Y}_{n}} , \qquad equation ( 1 )$$

wherein conductances

$${Y}_{iso +} = \frac{1}{{R}_{iso +}} , {Y}_{iso -} = \frac{1}{{R}_{iso -}} , {Y}_{iso\_mid} = \frac{1}{{R}_{iso\_mid}} , {Y}_{p} = \frac{1}{{R}_{p}} and {Y}_{n} = \frac{1}{{R}_{n}} .$$

In block 508, isolation detection engine 1418 may close a second set of switches of the corresponding isolation detection circuitry 150 of the first battery 302 and of the second battery 304 and sense a second voltage V_{s_b} between the coupling point 402 and the chassis ground 310.

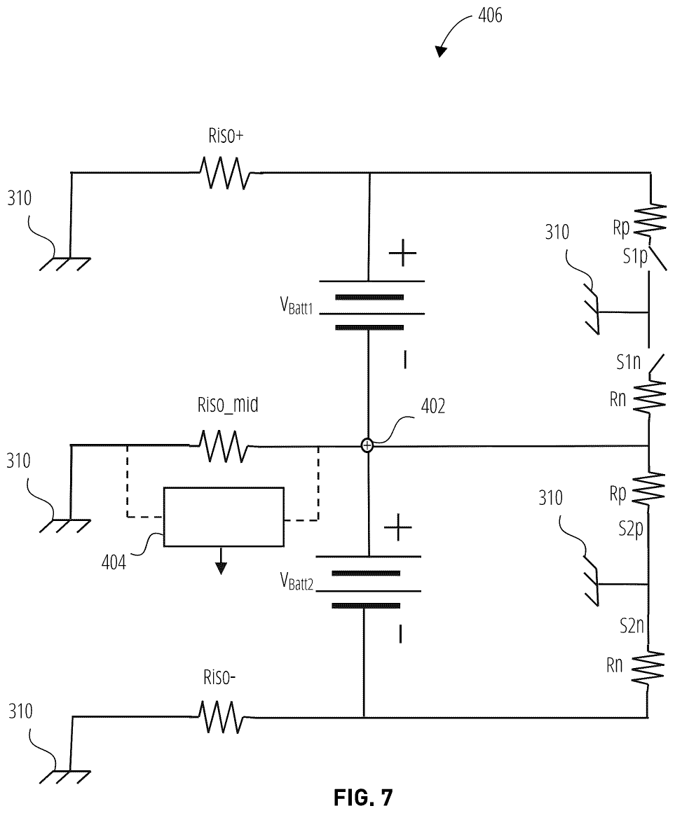

More specifically, the second set of switches include switches S2p and S2n (i.e., all switches of the second battery 304), as shown in FIG. 7. The second voltage V_{s_b} may be obtained by:

$${V}_{s \_ b} = \frac{{V}_{Batt 1} {Y}_{iso +} - {V}_{Batt 2} ( {Y}_{iso -} + {Y}_{n} )}{{Y}_{iso +} + {Y}_{iso -} + {Y}_{iso \_ mid} + {Y}_{p} + {Y}_{n} ,} . \qquad equation ( 2 )$$

In block 510, isolation detection engine 1418 may compute the total isolation resistance Rᵢₛₒ_{ₜₒₜₐₗ} comprising (a) a resistance between a positive terminal of the first battery and the chassis ground, (b) the resistance between the coupling point and the chassis ground, and (c) the resistance between a negative terminal of the second battery and the chassis ground. This may be based on at least the first voltage and the second voltage.

More specifically, based on equation (1) and equation (2),

$${Y}_{iso +} + {Y}_{iso -} + {Y}_{iso \_ mid} = \frac{{V}_{Batt 1} {Y}_{p}}{{V}_{s \_ a} - {V}_{s \_ b}} - ( {Y}_{p} + {Y}_{n} ) .$$

Thus, the total isolation resistance Rᵢₛₒ_{ₜₒₜₐₗ} can be computed by:

$${R}_{{iso}_{total}} = \frac{1}{{Y}_{iso +} + {Y}_{iso -} + {Y}_{iso \_ mid}} = \frac{{V}_{s \_ a} - {V}_{s \_ b}}{{V}_{Batt 1} {Y}_{p} - ( {V}_{s \_ a} - {V}_{s \_ b} ) ( {Y}_{p} + {Y}_{n} ) .}$$

Yₚ, Yₙ may be provided by a manufacturer of the resistors of the isolation detection circuitries 150, Bₐₜₜ₁ may be measured by the BMS 204, and V_{s_a}, and V_{s_b} may be measured by the voltage measurement device 404.

The computation of Rᵢₛₒ_{ₜₒₜₐₗ} as

$$\frac{{V}_{s \_ a} - {V}_{s \_ b}}{{V}_{Batt 1} {Y}_{p} - ( {V}_{s \_ a} - {V}_{s \_ b} ) ( {Y}_{p} + {Y}_{n} ) .}$$

is as follows:

$${V}_{s \_ a} = \frac{{V}_{Batt 1} ( {Y}_{iso +} + {Y}_{p} ) - {V}_{Batt 2} ( {Y}_{iso -} + {Y}_{n} )}{{Y}_{iso +} + {Y}_{iso -} + {Y}_{iso \_ mid} + {Y}_{p} + {Y}_{n}} , thus$$

$${V}_{{s}_{a}} ( {Y}_{iso +} + {Y}_{iso -} + {Y}_{{iso}_{mid}} + {Y}_{p} + {Y}_{n} ) = {V}_{Batt 1} {Y}_{iso +} - {V}_{Batt 2} ( {Y}_{iso -} + {Y}_{n} ) + {V}_{Batt 1} {Y}_{p} \qquad equation ( 3 )$$

$${V}_{s \_ b} = \frac{{V}_{Batt 1} {Y}_{iso +} - {V}_{Batt 2} ( {Y}_{iso -} + {Y}_{n} )}{{Y}_{iso +} + {Y}_{iso -} + {Y}_{iso \_ mid} + {Y}_{p} + {Y}_{n}} , thus$$

$${V}_{{s}_{b}} ( {Y}_{iso +} + {Y}_{iso -} + {Y}_{iso \_ mid} + {Y}_{p} + {Y}_{n} ) = {V}_{Batt 1} {Y}_{iso +} - {V}_{Batt 2} ( {Y}_{iso -} + {Y}_{n} ) \qquad equation ( 4 )$$

Subtraction equation (4) from equation (3) provides that

$$( {V}_{{s}_{a}} - {V}_{{s}_{b}} ) ( {Y}_{iso +} + {Y}_{iso -} + {Y}_{{iso}_{mid}} + {Y}_{p} + {Y}_{n} ) = {V}_{Batt 1} {Y}_{p} , thus {Y}_{iso +} + {Y}_{iso -} + {Y}_{iso \_ mid} = \frac{{V}_{Batt 1} {Y}_{p}}{{V}_{s \_ a} - {V}_{s \_ b}} - ( {Y}_{p} + {Y}_{n} ) ,$$

and therefore,

$${R}_{{iso}_{total}} = \frac{1}{{Y}_{iso +} + {Y}_{iso -} + {Y}_{iso \_ mid}} = \frac{{V}_{s \_ a} - {V}_{s \_ b}}{{V}_{Batt 1} {Y}_{p} - ( {V}_{s \_ a} - {V}_{s \_ b} ) ( {Y}_{p} + {Y}_{n} ) .}$$

In an aspect, the BMS 204 or a processor may automatically and/or periodically perform the measurement of the total isolation resistance and initiate corresponding safety actions when the total isolation resistance is below a predetermined safety threshold. The safety action may comprise providing a warning to an operator. The safety action may alternatively comprise turning off the first battery 302 and/or the second battery 304.

In an aspect, the warning may be provided when the total isolation resistance (more specifically, in some cases, the total isolation resistance per bur or maximum working voltage) is below 500 Ohm/V (i.e., Total isolation resistance per bus voltage in an example case). Responsive to the total isolation resistance per bus voltage falling below 100 Ohm/V in the example case, the first battery 302 and second battery 304 may be shut down/disconnected.

The first set of switches and the second set of switches may be selected to create different electrical paths in the power supply system 406 in different scenarios, each scenario having a predetermined relationship between voltages measured by the voltage measurement device 404, voltages of the first and second batteries, battery-to-chassis isolations resistances (Riso+, Riso−, Riso_mid) and resistances of the isolation detection circuitries 150 (Rp, Rn) such that the predetermined relationships may be analyzed and utilized to obviate individual computation of the battery-to-chassis isolation resistances (Riso+, Riso−, Riso_mid) while still being able to compute the total isolation resistance Rᵢₛₒ_{ₜₒₜₐₗ}.

More generally, different sets of switches that are part of the isolation detection circuitries 150 of series coupled battery packs may be selected as long as the selection can create different electrical paths or different interconnections and functional dependencies among constituent elements of the circuit such that the total isolation resistance can be computed based on at least measurement of a first voltage and a second voltage and individual computation any of Riso+, Riso−, and Riso_mid, can be obviated.

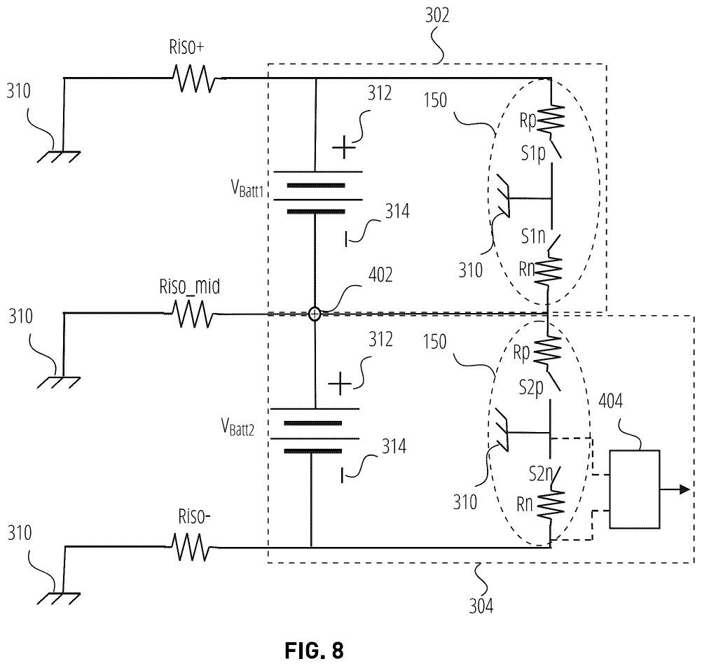

Though the first voltage V_{s_a} between the coupling point 402 and a chassis ground 310 and the second voltage V_{s_b} between the coupling point 402 and the chassis ground 310 may be sensed directly by the voltage measurement device 404 placed across Riso_mid, the first voltage and the second voltage may alternatively be obtained indirectly by other means such as by sensing a voltage, Vx, across second resistor Rn of second battery 304 as shown in FIG. 8 and computing the first voltage and/or second voltage based on Vx.

Specifically, for first voltage V_{s_a}, Vx_a=Vbatt2+V_{s_a}. For second voltage V_{s_b}, Vx_b=Vbatt2+Va_b. In some applications, it may be easier to measure Vx, when closing the first and second set of switches, and thus the first and second voltages may be obtained from Vx accordingly.

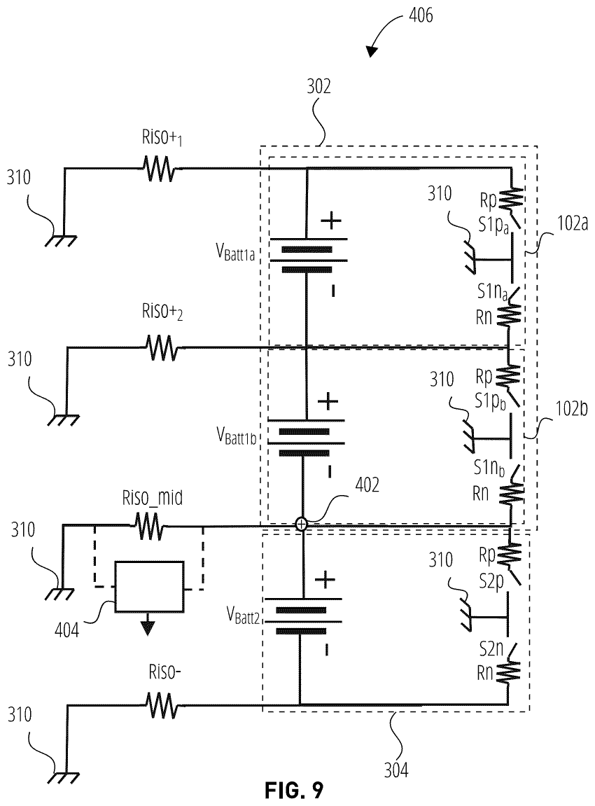

In an aspect, as shown in FIG. 9-FIG. 13, the first battery 302 and/or the second battery 304 may each comprise a plurality of battery packs 102 coupled in series. More specifically, a plurality of adjacent packs coupled in series may be treated as one battery for computing the total isolation resistance by adding voltages of the plurality of adjacent packs together.

As shown in FIG. 9, the first battery 302 comprises battery pack 102a and battery pack 102b. Battery pack 102a and battery pack 102b are coupled in series and may together be coupled in series with the second battery 304. By summing the voltages of battery pack 102a and battery pack 102b (VBatt1a+VBatt1b), the voltage of the first battery 302 can be obtained for computations described herein. Further, by obtaining the parallel resistance of the battery-to-chassis isolation resistances (Riso+1, Riso+2), the battery-to-chassis isolation resistance of the first battery 302 (Riso+, i.e., the resistance between the positive terminal 312 of the first battery 302 and the chassis ground 310) may be obtained for computations herein.

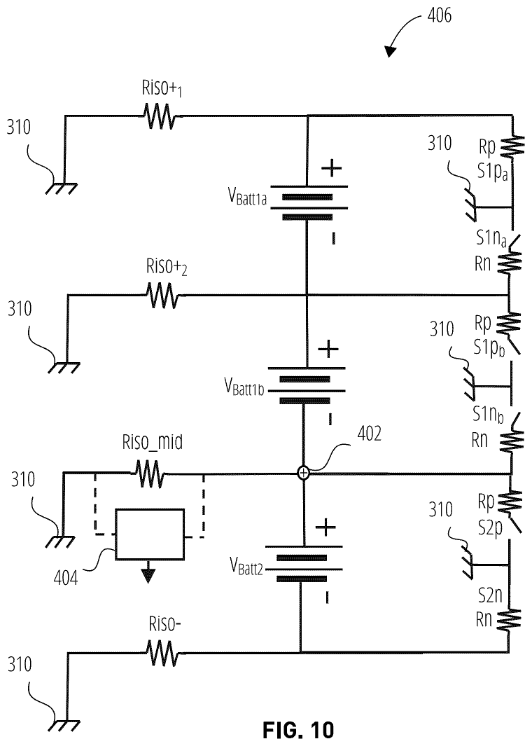

The first set of switches that may be closed to sense or obtain the first voltage V_{s_a} in the system of FIG. 9 is shown in FIG. 10. More specifically, the first switch S1pa (i.e., “a most positive switch”) of the first battery 302 and the second switch S2n of the second battery 304 may be closed to obtain or sense the first voltage V_{s_a} between the coupling point 402 and the chassis ground 310.

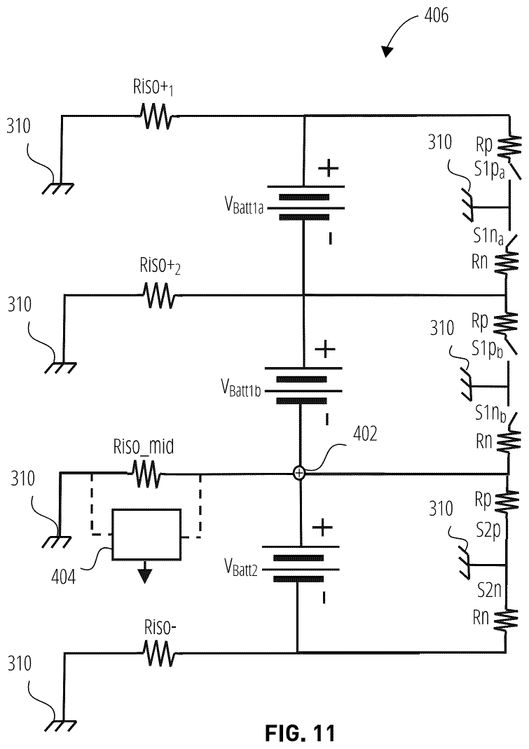

The second set of switches that may be closed to sense or obtain the second voltage V_{s_b} in the system of FIG. 9 is shown in FIG. 11. More specifically, the first switch S2p of the second battery 304 and the second switch S2n of the second battery 304 (i.e., all switches of the second battery 304) may be closed to obtain or sense the second voltage V_{s_b} between the coupling point 402 and the chassis ground 310.

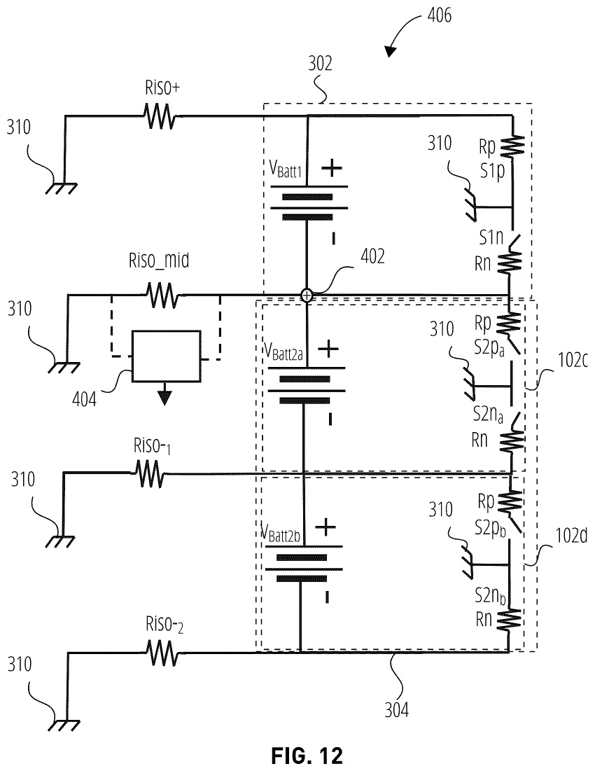

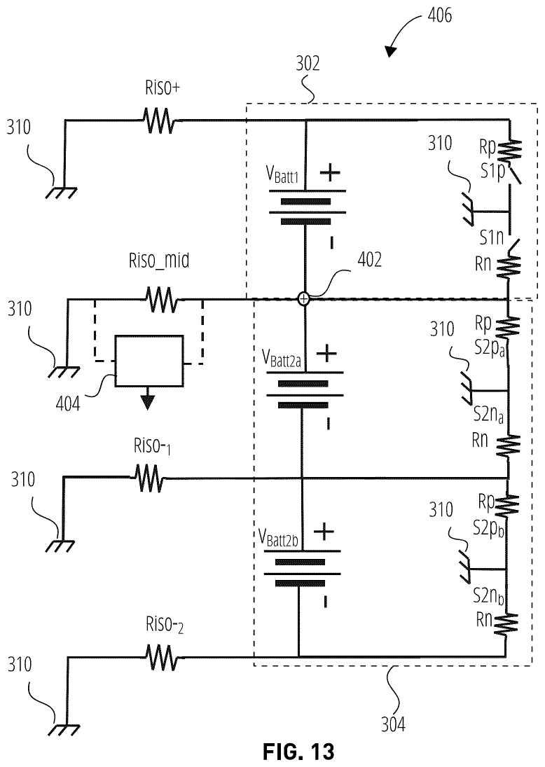

Alternatively, to the first battery 302 comprising a plurality of battery packs, the second battery 304 may comprise the plurality of battery packs as shown in FIG. 12-FIG. 13.

Specifically, FIG. 12-FIG. 13 show that second battery 304 comprises battery pack 102c and battery pack 102d which are coupled in series. The second battery 304 is also coupled in series with the first battery 302. By summing the voltages of battery pack 102c and battery pack 102d (VBatt2a+VBatt2b), the voltage of the second battery 304 can be obtained for computations described herein. Further, by obtaining the parallel resistance of the battery-to-chassis isolation resistances (Riso−1, Riso−2), the battery-to-chassis isolation resistance of the second battery 304 (Riso−, i.e., the resistance between the negative terminal 314 of the second battery 304 and the chassis ground 310) may be obtained for computations herein.

As shown in FIG. 12, the first set of switches that may be closed to sense or obtain the first voltage V_{s_a} between the coupling point 402 and the chassis ground 310 is the first switch S1p of the first battery 302 and the second switch S2nb (i.e., “a most negative switch”) of the second battery 304.

As shown in FIG. 13, the second set of switches that may be closed to sense or obtain the second voltage V_{s_b} between the coupling point 402 and the chassis ground 310 is all switches of the second battery 304.

Of course, the examples shown herein are not meant to be limiting as other examples may be obtained in view of the descriptions and figured provided. For example, the first battery 302 and/or the second battery 304 may each comprise three or four or ten battery packs 102 coupled in series with each other.

### Example Computer Platform

As discussed above, functions relating to methods and systems for isolation detection can use of one or more computing devices connected for data communication via wireless or wired communication. FIG. 14 is a functional block diagram illustration of a computer hardware platform that can be used to control various aspects of a suitable computing environment in which the process discussed herein can be controlled. While a single computing device is illustrated for simplicity, it will be understood that a combination of additional computing devices, program modules, and/or combination of hardware and software can be used as well. The computer platform 1400 may include a central processing unit (CPU) 1404, a hard disk drive (HDD) 1406, random access memory (RAM) and/or read only memory (ROM) 1408, a keyboard 1410, a mouse 1412, a display 1414, and a communication interface 1416, which are connected to a system bus 1402.

In one embodiment, the hard disk drive (HDD) 1406, has capabilities that include storing a program that can execute various processes, such as the isolation detection engine 1418, in a manner described herein. The isolation detection engine 1418 may have various modules configured to perform different functions. For example, there may be a process module 1420 configured to control the different routines discussed herein and others. There may be a total isolation resistance module 1422 operable to compute the total isolation resistance of a plurality of modular battery packs coupled in series together by controlling the switches of the corresponding isolation detection circuitries 150 that are provided in each battery pack.

For the sake of brevity, conventional techniques related to making and using aspects of the disclosure may or may not be described in detail herein. In particular, various aspects of manufacturing and computing systems and specific programs to implement the various technical features described herein may be well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or system. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram, or the steps (or operations) described therein without departing from the spirit of the disclosure. For instance, the actions can be performed in a differing order or actions can be added, deleted, or modified.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” and similar terms can include a range of ±8% or 5%, or 2% of a given value.

The present disclosure may be a system, a method, and/or a computer program product at any possible technical detail level of integration. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A system comprising:
a first battery comprising first isolation detection circuitry;
a second battery comprising second isolation detection circuitry and coupled to the first battery in series at a coupling point; and
a processor configured to:
close a first set of switches of the first and second isolation detection circuitry, and obtain, via a voltage measurement device, a first voltage between the coupling point and a chassis ground;
close a second set of switches of the first and second isolation detection circuitry, and obtain, via a voltage measurement device, a second voltage between the coupling point and the chassis ground;
compute a total isolation resistance based on (a) a resistance between a positive terminal of the first battery and the chassis ground, (b) the resistance between the coupling point and the chassis ground, and (c) the resistance between a negative terminal of the second battery and the chassis ground,
wherein the total isolation resistance is computed based on at least the first voltage and the second voltage.

2. The system of claim 1, wherein the first battery and/or the second battery comprise one or more battery packs coupled in series.

3. The system of claim 2, wherein each of the one or more battery packs coupled in series comprises the corresponding isolation detection circuitry.

4. The system of claim 1, wherein each of the first and second isolation detection circuitry comprises:
a first switch coupled to the chassis ground;
a second switch coupled to the chassis ground;
a first resistor coupling a positive terminal of the battery to the first switch; and
a second resistor coupling a negative terminal of the battery to the second switch;

5. The system of claim 1, wherein the processor is configured to compute the total isolation resistance as
$${R}_{{iso}_{total}} = \frac{{V}_{s \_ a} - {V}_{s \_ b}}{{V}_{Batt 1} {Y}_{p} - ( {V}_{s \_ a} - {V}_{s \_ b} ) ( {Y}_{p} + {Y}_{n} ) ,}$$
wherein
$${Y}_{p} = \frac{1}{{R}_{p} ,} {Y}_{n} = \frac{1}{{R}_{n} ,}$$
V_{s_a} is the first voltage, V_{s_b} is the second voltage, V_{Batt1} is the voltage of the first battery, Rₚ is a resistance of the first resistor, and Rₙ is a resistance of the second resistor.

6. The system of claim 1, further comprising:
a voltage measurement device;
wherein the processor is configured to obtain the first voltage and the second voltage using the voltage measurement device.

7. A method for determining an isolation resistance in a system comprising a first battery and a second battery coupled in series at a coupling point, each battery including a corresponding isolation detection circuitry, the method comprising:
closing a first set of switches of the corresponding isolation detection circuitry of the first battery and of the second battery, and obtaining a first voltage between the coupling point and a chassis ground;
closing a second set of switches of the corresponding isolation detection circuitry of the first battery and of the second battery, and obtaining a second voltage between the coupling point and the chassis ground;
computing a total isolation resistance comprising (a) a resistance between a positive terminal of the first battery and the chassis ground, (b) the resistance between the coupling point and the chassis ground, and (c) the resistance between a negative terminal of the second battery and the chassis ground,
wherein the computing is performed based on at least the first voltage and the second voltage.

8. The method of claim 7, wherein
the first set of switches and the second set of switches are selected to create electrical paths in different scenarios such that the total isolation resistance is computed based on at least the first voltage and the second voltage without a need to individually compute any of (a), (b), and (c).

9. The method of claim 7, wherein the computing is performed automatically.

10. The method of claim 7, wherein the first battery and/or the second battery comprise one or more battery packs coupled in series.

11. The method of claim 9, wherein each of the one or more battery packs coupled in series comprises the corresponding isolation detection circuitry.

12. The method of claim 11, wherein a plurality of adjacent packs coupled in series are treated as one battery for computing the total isolation resistance by adding voltages of the plurality of adjacent packs together.

13. The method of claim 7, wherein the corresponding isolation detection circuitry of each battery is formed by:
coupling one side of a first resistor to a positive terminal of the battery and another side of the first resistor to a first switch;
coupling the first switch to the chassis ground;
coupling one side of a second resistor to a negative terminal of the battery and another side of the second resistor to a second switch; and
coupling the second switch to the chassis ground.

14. The method of claim 13, wherein the total isolation resistance is computed by
$${R}_{{iso}_{total}} = \frac{{V}_{s \_ a} - {V}_{s \_ b}}{{V}_{Batt 1} {Y}_{p} - ( {V}_{s \_ a} - {V}_{s \_ b} ) ( {Y}_{p} + {Y}_{n} ) ,}$$
wherein
$${Y}_{p} = \frac{1}{{R}_{p} ,} {Y}_{n} = \frac{1}{{R}_{n} ,}$$
V_{s_a} is the first voltage, V_{s_b} is the second voltage, Bₐₜₜ₁ is the voltage of the first battery, Rₚ is a resistance of the first resistor, and Rₙ is a resistance of the second resistor.

15. The method of claim 14, wherein responsive to computing the total isolation resistance to be below a predetermined safety threshold, a safety action is performed.

16. The method of claim 15, wherein the safety action comprises providing a warning to an operator.

17. The method of claim 15, wherein the safety action comprises turning off the first battery and/or second battery.

18. The method of claim 13,
wherein closing the first set of switches comprises closing the first switch of the first battery and closing the second switch of the second battery,
wherein the first voltage is represented by
$${V}_{s \_ b} = \frac{{V}_{Batt 1} {Y}_{iso +} - {V}_{Batt 2} ( {Y}_{iso -} + {Y}_{n} )}{{Y}_{iso +} + {Y}_{iso -} + {Y}_{iso \_ mid} + {Y}_{p} + {Y}_{n} ,}$$
wherein
$${Y}_{iso +} = \frac{1}{{R}_{iso +} ,} {Y}_{iso -} = \frac{1}{{R}_{iso -} ,} {Y}_{iso \_ mid} = \frac{1}{{R}_{iso \_ mid} ,} {Y}_{p} = \frac{1}{{R}_{p} ,} {Y}_{n} = \frac{1}{{R}_{n} ,}$$
and
wherein V_{s_a} is the first voltage, V_{Batt1} is the voltage of the first battery, V_{Batt2} is the voltage of the second battery, Rᵢₛₒ₊ is (a), R_{iso_mid} is (b), Rᵢₛₒ₋ is (c), Rₚ is a resistance of the first resistor, and Rₙ is a resistance of the second resistor.

19. The method of claim 13,
wherein closing the second set of switches comprises closing the first switch of the second battery and closing the second switch of the second battery,
wherein the second voltage is represented by
$${V}_{s \_ b} = \frac{{V}_{Batt 1} {Y}_{iso +} - {V}_{Batt 2} ( {Y}_{iso -} + {Y}_{n} )}{{Y}_{iso +} + {Y}_{iso -} + {Y}_{iso \_ mid} + {Y}_{p} + {Y}_{n} ,}$$
wherein
$${Y}_{iso +} = \frac{1}{{R}_{iso +} ,} {Y}_{iso -} = \frac{1}{{R}_{iso -} ,} {Y}_{iso \_ mid} = \frac{1}{{R}_{iso \_ mid} ,} {Y}_{p} = \frac{1}{{R}_{p} ,} {Y}_{n} = \frac{1}{{R}_{n} ,}$$
and
wherein V_{s_b} is the second voltage, V_{Batt1} is the voltage of the first battery, V V_{Batt2} is the voltage of the second battery, Rᵢₛₒ₊ is (a), R_{iso_mid} is (b), Rᵢₛₒ₋ is (c), Rₚ is a resistance of the first resistor, and Rₙ is a resistance of the second resistor.

20. A non-transitory computer-readable storage medium storing instructions which, when executed by a processor, causes a computer system to:
close a first set of switches of a corresponding isolation detection circuitry of a first battery and of a second battery, and obtain, via a voltage measurement device, a first voltage between a coupling point, formed between a negative terminal of the first battery and a positive terminal of the second battery, and a chassis ground;
close a second set of switches of the corresponding isolation detection circuitry of the first battery and of the second battery, and obtain, via a voltage measurement device, a second voltage between the coupling point and the chassis ground;
compute a total isolation resistance comprising (a) a resistance between a positive terminal of the first battery and the chassis ground, (b) the resistance between the coupling point and the chassis ground, and (c) the resistance between a negative terminal of the second battery and the chassis ground,
wherein the total isolation resistance is computed based on at least the first voltage and the second voltage.
